(19) United States
(12) Patent Application Publication
(10) Pub. No.: US 2026/0211339 A1
(43) Pub. Date: Jul. 23, 2026

(54) SINGLE PHOTON SOURCE DEVICE

(71) Applicant: Korea Research Institute of Standards and Science, Daejeon (KR)

(72) Inventors: Kee Suk HONG, Daejeon (KR); Hee Jin LIM, Daejeon (KR); Dong Hoon LEE, Sejong-si (KR); In Ho BAE, Daejeon (KR)

(21) Appl. No.: 19/443,653

(22) Filed: Jan. 8, 2026

(30) Foreign Application Priority Data
Jan. 9, 2025 (KR) 10-2025-0003650

(51) Int. Cl. G03F 7/00; G03F 7/20

(52) U.S. Cl. CPC G03F 7/70616; G03F 7/2004; G03F 7/706849

(57) ABSTRACT

Disclosed herein is a single photon source device according to embodiments, which includes a microscope part including a stage that is three-dimensionally movable, a wafer disposed on the stage, a laser part configured to emit light to the wafer, and a single-mode fiber (SMF) input/output module configured to emit an optical signal reflected by the wafer to an outside, wherein the wafer has a surface on which the light is incident and a first mapping chart is disposed, and the first mapping chart includes a first sub-chart and a second sub-chart, each of which includes a plurality of letters spaced a predetermined distance from each other.

### CROSS-REFERENCE TO RELATED APPLICATION

This application claims priority to and the benefit of Korean Patent Application No. 10-2025-0003650, filed on Jan. 9, 2025, the disclosure of which is incorporated herein by reference in its entirety.

### BACKGROUND

### 1. Field of the Invention

Embodiments relate to a single photon source device.

### 2. Discussion of Related Art

Quantum information and communication technology is a core of the future information and communication technology and has the advantages of high security and fast processing speed. One fundamental factor of the quantum information and communication technology is a single photon source. A single photon source is a device capable of generating photons, which are quantum units of electromagnetic waves, one by one and transmitting the photons, and performs an essential role in various fields such as quantum cryptography communication, quantum computing, and quantum metrology. However, most of the currently commercialized single photon sources operate in cryogenic environments or are pseudo single photon sources and have problems of security and reliability.

Single photon sources perform roles for maximizing security in information and communication systems. In particular, in quantum cryptography communication, a single photon provides security by utilizing no-cloning theorem, and, when a multi-photon state occurs, a problem may occur in security. Light sources used in currently commercialized quantum cryptography systems are pseudo single photon sources that attenuate output power of a laser to generate a state close to a single photon on average. However, these pseudo single photon sources have the disadvantage of being vulnerable in security due to the high probability of multi-photon generation.

A deterministic single photon source is needed to solve this problem. The deterministic single photon source may deterministically generate a single photon in the specific time and space and thus provide the high security and reliability in the quantum cryptography communication and other quantum technologies.

The single photon source is broadly divided into two types of sources according to a generation method. The first is a heralded single photon source uses a method of generating a pair of photons using a nonlinear optical phenomenon, and then one of the pair of photons heralds occurrence probability of the other photon. The second is a single-emitter single photon source is controlled by a method of generating only one photon in a specific single atom, a quantum dot, or defect structure.

Conventional single photon source systems have a very large scale that may be implemented in a laboratory and are formed using various types of devices. Therefore, the conventional single photon source systems are not suitable for light sources for quantum communication or other systems. In addition, it has the disadvantage that a light source is very difficult to find and stabilization is difficult to achieve.

### SUMMARY OF THE INVENTION

Embodiments provide a single photon source device capable of reproducibly finding a position of a single photon.

In addition, embodiments provide a single photon source device capable of continuously measuring a light emission intensity.

In addition, embodiments provide a single photon source device capable of operating at room temperature and being miniaturized.

In addition, embodiments provide a single photon source device with high precision and high stability of photon generation.

Problems to be solved in the embodiments are not limited to the above-described problems, and objects and effects which may be determined from the solutions and the embodiments of the problems that are described below are also included.

A single photon source device according to embodiments includes a microscope part including a stage that is three-dimensionally movable, a wafer disposed on the stage, a laser part configured to emit light to the wafer, and a single-mode fiber (SMF) input/output module configured to emit an optical signal reflected by the wafer to an outside, wherein the wafer has a surface on which the light is incident and a first mapping chart is disposed, and the first mapping chart includes a first sub-chart and a second sub-chart, each of which includes a plurality of letters spaced a predetermined distance from each other.

The plurality of letters included in the first sub-chart and the plurality of letters included in the second sub-chart may be spaced a predetermined distance from each other in a first direction and a second direction perpendicular to the first direction, respectively.

The plurality of letters included in the first sub-chart and the plurality of letters included in the second sub-chart may be written in directions perpendicular to each other.

The plurality of letters included in the first sub-chart may be written in the first direction, and the plurality of letters included in the second sub-chart may be written in the second direction.

The plurality of letters included in the first sub-chart may be capital letters of English alphabet, and the plurality of letters included in the second sub-chart may be small letters of English alphabet.

The plurality of letters included in the first sub-chart may include AA to AZ, BA to BZ, and CA to CZ.

The plurality of letters included in the second sub-chart may include aa to az, ba to bz, and ca to cz.

The wafer may include a second mapping chart spaced a predetermined distance from the first mapping chart in the first direction.

The distance between the first mapping chart and the second mapping chart may range from 0.9 cm to 1.1 cm in the first direction.

A distance between two adjacent letters among the plurality of letters included in the first sub-chart may range from 90 μm to 110 μm.

The first mapping chart may include a plurality of cross patterns disposed between the plurality of letters included in the first sub-chart and between the plurality of letters included in the second sub-chart.

A distance between two adjacent cross patterns among the plurality of cross patterns may range from 20 μm to 30 μm.

The plurality of letters of the first sub-chart and the plurality of letters of the second sub-chart may protrude from a surface of the wafer in a direction in which light is incident.

The single photon source device according to embodiments may further include a camera part configured to receive light reflected by the wafer and acquire an image of the wafer.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram of a single photon source device according to an embodiment;

FIG. 2 is a schematic diagram of the single photon source device according to the embodiment;

FIGS. 3 and 4 are schematic diagrams of a wafer of the single photon source device according to the embodiment;

FIG. 5 is a diagram illustrating a mapping chart of the wafer of the single photon source device according to the embodiment;

FIG. 6 shows an enlarged diagram and image of the wafer of the single photon source device according to the embodiment;

FIG. 7 is an image illustrating the result of mapping a position of a single photon source through the single photon source device according to the embodiment;

FIG. 8 is a reference diagram illustrating an operation of etching the wafer of the single photon source device according to the embodiment;

FIG. 9 shows images illustrating a state of the etched wafer of the single photon source device according to the embodiment;

FIGS. 10A to 10C are images of the single photon source device according to the embodiment; and

FIGS. 11 to 13, 14A, and 14B are graphs showing effects of the single photon source device according to the embodiment.

### DETAILED DESCRIPTION OF EXEMPLARY EMBODIMENTS

Hereinafter, exemplary embodiments of the present invention will be described in detail with reference to the accompanying drawings.

However, the technical idea of the present invention is not limited to some embodiments to be described but may be implemented in various different forms, and, within the scope of the technical idea of the present invention, one or more among components in the embodiments may be used by being selectively combined and substituted.

Further, unless specifically defined and described, terms used in the embodiments of the present invention (including technical and scientific terms) may be construed as meanings which are generally understood by those skilled in the art to which the present invention pertains, and generally used terms such as terms defined in the dictionary may be interpreted in consideration of the contextual meaning of the related art.

In addition, terms used in the embodiments of the present invention are intended to describe the embodiments and are not intended to limit the present invention.

In the present specification, the singular forms may include the plural forms unless the context clearly dictates otherwise, and, when described as “at least one (or one or more) among A, B, and (or) C,” it may include one or more among all combinations in which A, B, and C can be combined.

In addition, in describing components of embodiments of the present invention, the terms first, second, A, B, (a), (b), and the like can be used.

These terms are intended to distinguish one component from other components, but the nature and the order or sequence of the components is not limited by those terms.

In addition, when a component is described as being “linked,” “coupled,” or “connected” to another component, the component is not only directly linked, coupled, or connected to another component, but also “linked,” “coupled,” or “connected” to another component with still another component disposed between the component and another component.

In addition, when a component is described as being formed or disposed “on (above) or under (below)” of another component, the term “on (above) or under (below)” includes not only when two components are in direct contact with each other, but also when one or more of other components are formed or disposed between the two components. Further, when a component is described as being “on (above) or below (under),” the description may include the meanings of an upward direction and a downward direction based on one component.

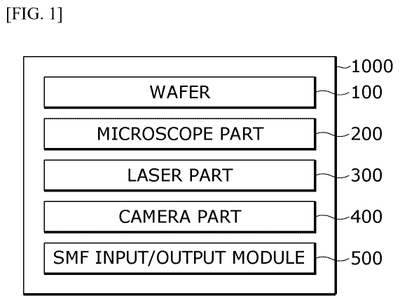

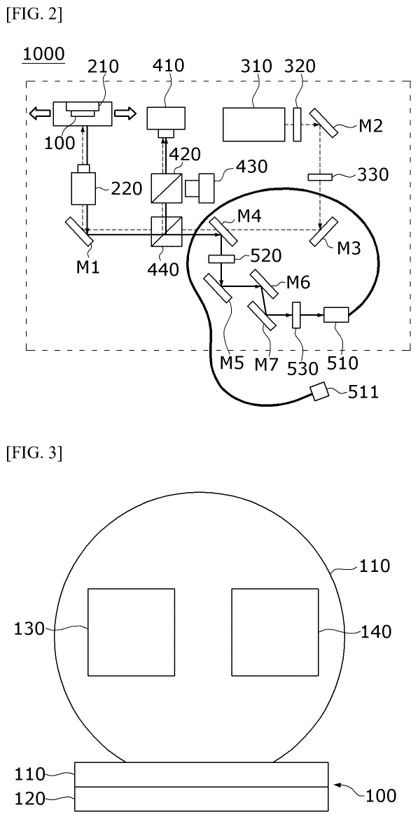

FIG. 1 is a block diagram of a single photon source device according to an embodiment, and FIG. 2 is a schematic diagram of the single photon source device according to the embodiment.

Referring to FIGS. 1 and 2, a single photon source device 1000 according to an embodiment may include a wafer 100, a microscope part 200, a laser part 300, a camera part 400, and a single-mode fiber (SMF) input/output module 500.

The wafer 100 may receive light and reflect the received light as an optical signal. The wafer 100 may receive light and generate a single photon. The wafer 100 may be a thin substrate. The wafer 100 may include a substrate and a wafer layer. For example, the wafer 100 may be in the form in which a GaN wafer is stacked on a sapphire substrate. The wafer 100 according to the embodiment may have an effect of allowing the single photon source to operate at room temperature using GaN. For example, the wafer 100 is a p-type semiconductor and may include a GaN thin film doped with magnesium (Mg). In addition, for example, a diameter of the wafer 100 is 2 inches, and a thickness thereof is 0.43 mm, and a thickness of the GaN thin film is 4.5 μm so as to form an important active layer of a photoelectron and high-power electronic device. A process of the wafer 100 may be a photolithography (optical lithography) process for a GaN wafer grown on a sapphire substrate. A photoresist (PR) may be uniformly applied onto a wafer surface with a thickness of 1.5 μm, and then a process of transferring a mask pattern to the wafer through ultraviolet (UV) exposure is performed, and the transferred pattern may be selectively etched or deposited through a subsequent process.

The wafer 100 may be disposed on a stage 210 of the microscope part 200. The wafer 100 may be disposed on the stage 210 to move three-dimensionally. The wafer 100 may be disposed on the stage 210 to finely move three-dimensionally and thus move very finely and precisely. The wafer 100 may move on the stage 210 to receive light emitted from the laser part 300.

The microscope part 200 may include the stage 210, an objective lens 220, and a first mirror M1. The stage 210 on which the wafer 100 is disposed may fix the wafer 100. The stage 210 may perform a three-dimensional fine movement by moving in an X-axis, Y-axis, and Z-axis directions. Therefore, the stage 210 may finely move a position of the wafer 100 three-dimensionally. The objective lens 220 may change a path of the light to concentrate the light on the wafer 100 of the stage 210. In addition, the objective lens 220 may transmit an optical signal emitted from the wafer 100 to the outside. The objective lens 220 may be disposed between the stage 210 and the first mirror M1. The first mirror M1 may reflect light and change a path of the light to direct the light toward the objective lens 220. In addition, the first mirror M1 may change the path of the light passing through the objective lens 220 to direct the light toward a second splitter 440. Here, a Z-axis direction may correspond to a direction in which light is incident on the wafer 100, and an X-axis direction and a Y-axis direction may correspond to a first direction and a second direction, respectively.

The laser part 300 may include a light source 310, a first filter 320, a second mirror M2, a second filter 330, a third mirror M3, and a fourth mirror M4. The light source 310 may output and radiate light. The light source 310 may be a pump light source that emits laser-pump light. The first filter 320 and the second filter 330 may filter a portion of the light emitted from the laser part 300. The first filter 320 may include a variable neutral density (ND) filter. In addition, the second filter 330 may include a band pass filter. The second mirror M2 may be disposed between the first filter 320 and the second filter 330. The second mirror M2 may reflect the light passing through the first filter 320 toward the second filter 330. The third mirror M3 may be disposed between the second filter 330 and the fourth mirror M4. The third mirror M3 may reflect the light passing through the second filter 330 toward the fourth mirror M4. The fourth mirror M4 may be disposed between the third mirror M3 and the second splitter 440. The fourth mirror M4 may change an optical path by selecting a portion of the light according to a wavelength of the light. The fourth mirror M4 may include a dichroic mirror. The fourth mirror M4 may transmit a portion of the light and reflect the remaining light. The light passing through the fourth mirror M4 may be directed toward the second splitter 440. In addition, the fourth mirror M4 may reflect the light passing through the second splitter 440 toward a third filter 520 of the SMF input/output module 500.

The camera part 400 may include a camera 410, a first splitter 420, a white light source 430, and the second splitter 440. The camera 410 may receive light reflected by the wafer 100 and acquire an image of the wafer 100. In addition, the camera 410 may receive the light radiated from the light source 310. The camera 410 may include a charge coupled device (CCD) camera. The first splitter 420 may transmit a portion of the light and reflect the remaining light. The first splitter 420 may pass the light reflected by the second splitter 440 to allow the light to reach the camera 410. The white light source 430 may emit white light. The white light emitted from the white light source 430 may reach the microscope part 200 through the splitter. The second splitter 440 may transmit a portion of the light and reflect the remaining light. The second splitter 440 may reflect a portion of the light emitted from the laser part 300 and transmit the remaining light. In addition, the second splitter 440 may reflect a portion of the light reflected by the wafer 100 and transmit the remaining light. The second splitter 440 may be disposed between the first mirror M1 and the fourth mirror M4. The single photon source device 1000 may include the camera part 400 and, thus, facilitate optical alignment. The single photon source device 1000 may emit light different from that of the light source 310 through the white light source 430, thereby performing optical alignment easily. In addition, a light emission intensity of the wafer may be continuously measured through the camera part.

The SMF input/output module 500 may include an SMF 510, the third filter 520, a fourth filter 530, a fifth mirror M5, a sixth mirror M6, and a seventh mirror M7. The SMF 510 may refer to a single mode optical fiber. The SMF 510 may transmit and receive an optical signal. The SMF 510 may emit the optical signal reflected by the wafer 100 to the outside. The optical signal may be emitted to the outside through an end 511 of the SMF 510. The third filter 520 may transmit the light signal reflected by the fourth mirror M4. The third filter 520 may include a long pass filter. The fifth mirror M5, the sixth mirror M6, and the seventh mirror M7 may sequentially reflect the light passing through the third filter 520 to allow the light to reach the fourth filter 530. The fifth mirror M5, the sixth mirror M6, and the seventh mirror M7 may be disposed between the third filter 520 and the fourth filter 530. The fourth filter 530 may transmit the optical signal to allow the optical signal to reach the SMF 510. The fourth filter 530 may include a long-pass filter.

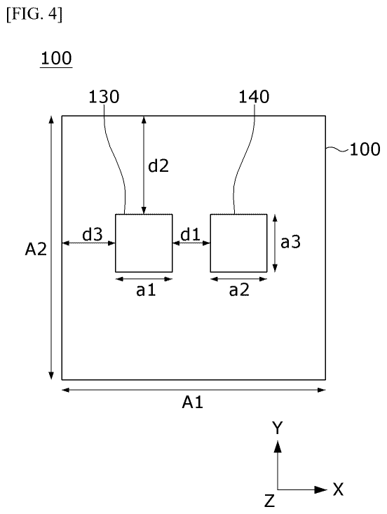

FIGS. 3 and 4 are schematic diagrams of a wafer of the single photon source device according to the embodiment.

FIG. 3 shows the wafer 100 when viewed from the side and the top. Referring to FIG. 3, the wafer 100 of the single photon source device may include a wafer layer 110 and a substrate 120. The wafer layer 110 may be disposed on the substrate 120. The wafer 100 may include a form in which the wafer layer 110 is stacked on the substrate 120. When the wafer 100 is viewed from the side, the wafer layer 110 and the substrate 120 may be stacked in a direction in which light is incident. The substrate 120 may include a sapphire substrate. The wafer layer 110 may include a GaN layer. The wafer layer 110 may be made of 100% GaN. The wafer 100 may include a GaN layer, thereby enabling the single photon source device to operate at room temperature. Each of the substrate 120 and the wafer layer 110 may have a predetermined thickness in the direction in which the light is incident. When the light is incident on the wafer layer 110, the light is reflected to generate a single photon. The single photon may be generated at a specific position inside the wafer layer 110. The wafer layer 110 may have predetermined widths in the first direction and the second direction. The wafer layer 110 may have widths ranging from 4.9 inches to 5.1 inches in the first direction and the second direction.

The wafer layer 110 may include a first mapping chart 130. The first mapping chart 130 may be disposed on a surface of the wafer layer 110 on which the light is incident. The first mapping chart 130 may have predetermined widths in the first direction perpendicular to the direction in which the light is incident (which may correspond to the X-axis direction on the drawing) and the second direction (which may correspond to the Y-axis direction on the drawing). The second direction may be a direction perpendicular to the first direction. In addition, the wafer layer 110 may include a second mapping chart 140. The second mapping chart 140 may be disposed to be spaced a predetermined distance from the first mapping chart 130 on the surface of the wafer layer 110 on which the light is incident. The first mapping chart 130 and the second mapping chart 140 may be disposed perpendicular to the direction in which the light is incident. That is, the first mapping chart 130 and the second mapping chart 140 may be disposed parallel to an upper surface of the wafer layer 110. The first mapping chart 130 and the second mapping chart 140 may be references during tracking of a single photon. When the camera part 400 captures an image of the wafer 100, the camera part 400 may map an exact position of a single photon based on the first mapping chart 130 and the second mapping chart 140.

The first mapping chart 130 and the second mapping chart 140 may be disposed a predetermined distance from each other. The first mapping chart 130 and the second mapping chart 140 may be spaced a predetermined distance from each other in the first direction. The first mapping chart 130 and the second mapping chart 140 may be disposed to be spaced a distance of 0.9 cm to 1.1 cm from each other in the first direction. For example, the first mapping chart 130 and the second mapping chart 140 may be disposed to be spaced a distance of 1 cm from each other in the first direction. The first mapping chart 130 and the second mapping chart 140 may be disposed within a predetermined from the end of the wafer layer 110. The first mapping chart 130 and the second mapping chart 140 may be spaced apart from an edge of the wafer layer 110 by 5.2 cm to 5.4 cm in the second direction. For example, the first mapping chart 130 and the second mapping chart 140 may be disposed to be spaced by 5.3 cm from the edge of the wafer layer 110 in the second direction. In addition, the first mapping chart 130 and the second mapping chart 140 may be spaced apart from the edge of the wafer layer 110 by 4.1 cm to 4.3 cm in the first direction. In addition, each of the first mapping chart 130 and the second mapping chart 140 may have predetermined widths in the first direction and the second direction. Each of the first mapping chart 130 and the second mapping chart 140 may have widths of 1.4 cm to 1.6 cm in the first direction and the second direction.

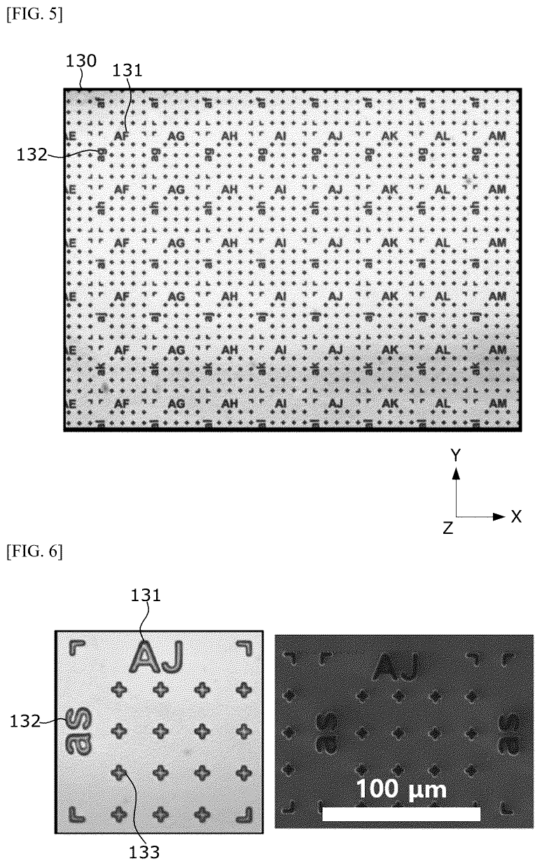

FIG. 5 is a diagram illustrating a mapping chart of the wafer of the single photon source device according to the embodiment, and FIG. 6 shows an enlarged diagram and image of the wafer of the single photon source device according to the embodiment.

Referring to FIGS. 5 and 6, the first mapping chart 130 may include a first sub-chart 131 and a second sub-chart 132, which include a plurality of letters spaced a predetermined distance from each other. Each of the first sub-chart 131 and the second sub-chart 132 may include a plurality of letters. The plurality of letters may be disposed to be spaced a predetermined distance from each other. The plurality of letters may be disposed to be spaced a predetermined distance from each other in the first direction and the second direction. That is, the plurality of letters may be disposed along a plurality of rows and columns. The first sub-chart 131 and the second sub-chart 132 may be disposed to overlap each other on the wafer layer 110.

The plurality of letters included in the first sub-chart 131 may be different from the plurality of letters included in the second sub-chart 132.

The plurality of letters included in the first sub-chart 131 may be capital letters of English alphabet. The plurality of letters included in the first sub-chart 131 may be different capital letters. Each of the plurality of letters included in the first sub-chart 131 may include two capital letters. The plurality of letters included in the first sub-chart 131 may include AA to AZ, BA to BZ, and CA to CZ. The plurality of letters included in the first sub-chart 131 may be sequentially enumerated in the order of AA to AZ, BA to BZ, and CA to CZ. For example, the plurality of letters disposed in a first row of the first sub-chart 131 may be AA to AZ, BA to BZ, and CA to CZ which are disposed sequentially to be spaced a predetermined distance from each other in the first direction. In addition, letters disposed in the same column may be identical to each other. For example, AA that is the plurality of letters in a first column of the first sub-chart 131 may be disposed to be spaced a predetermined distance from each other in the second direction. In addition, AB that is the plurality of letters in a second column of the first sub-chart 131 may be disposed to be spaced a predetermined distance from each other in the second direction. The plurality of letters included in the first sub-chart 131 may protrude in the direction in which the light is incident. The plurality of letters included in the first sub-chart 131 may each have a predetermined height in the direction in which light is incident. That is, the plurality of letters included in the first sub-chart 131 may protrude in a direction perpendicular to the surface of the wafer 100. Two adjacent letters among the plurality of letters included in the first sub-chart 131 may be spaced a predetermined distance from each other in the first direction and the second direction. The two adjacent letters among the plurality of letters included in the first sub-chart 131 may be spaced apart from each other by 90 μm to 110 μm in the first direction and the second direction. For example, the two adjacent letters among the plurality of letters included in the first sub-chart 131 may be disposed to be spaced apart from each other by 100 μm in the first direction and the second direction.

The plurality of letters included in the second sub-chart 132 may be small letters. The plurality of letters included in the second sub-chart 132 may be different small letters. Each of the plurality of letters included in the second sub-chart 132 may include two small letters. The plurality of letters included in the second sub-chart 132 may include aa to az, ba to bz, and ca to cz. The plurality of letters included in the second sub-chart 132 may be sequentially enumerated in the order of aa to az, ba to bz, and ca to cz. For example, the plurality of letters disposed in a first column of the second sub-chart 132 may aa to az, ba to bz, and ca to cz which are disposed sequentially to be spaced a predetermined distance from each other in the second direction. In addition, letters disposed in the same row may be identical to each other. For example, aa that is the plurality of letters disposed in a first row of the second sub-chart 132 may be disposed to be spaced a predetermined distance from each other in the second direction. In addition, ab that is the plurality of letters in a second row of the second sub-chart 132 may be disposed to be spaced a predetermined distance from each other in the second direction. The plurality of letters included in the second sub-chart 132 may protrude in the direction in which the light is incident. The plurality of letters included in the second sub-chart 132 may each have a predetermined height in the direction in which light is incident. That is, the plurality of letters included in the second sub-chart 132 may protrude in a direction perpendicular to the surface of the wafer 100. Two adjacent letters among the plurality of letters included in the second sub-chart 132 may be spaced a predetermined distance from each other in the first direction and the second direction. The two adjacent letters among the plurality of letters included in the second sub-chart 132 may be spaced apart from each other by 90 μm to 110 μm in the first direction and the second direction. For example, the two adjacent letters among the plurality of letters included in the second sub-chart 132 may be disposed to be spaced apart from each other by 100 μm in the first direction and the second direction.

The plurality of letters included in the first sub-chart 131 may be disposed in a direction different from a direction of the plurality of letters included in the second sub-chart 132. The plurality of letters included in the first sub-chart 131 and the plurality of letters included in the second sub-chart 132 may be written in directions perpendicular to each other. The plurality of letters included in the first sub-chart 131 may be written in the first direction. Two capital letters included in each of the plurality of letters included in the first sub-chart 131 may be disposed in the first direction. In addition, the plurality of letters included in the second sub-chart 132 may be written in the second direction. Two small letters included in each of the plurality of letters included in the second sub-chart 132 may be disposed in the second direction.

The first mapping chart 130 may include a plurality of cross patterns 133 spaced a predetermined distance from each other. The plurality of cross patterns 133 may be disposed between the plurality of letters included in the first sub-chart 131 and between the plurality of letters included in the second sub-chart 132. The plurality of cross patterns 133 may be disposed to be spaced a predetermined distance from each other in the first direction or the second direction. A distance between two adjacent cross patterns among the plurality of cross patterns 133 may range 20 μm to 30 μm. For example, the distance between the two adjacent cross patterns among the plurality of cross patterns 133 may be 25 μm.

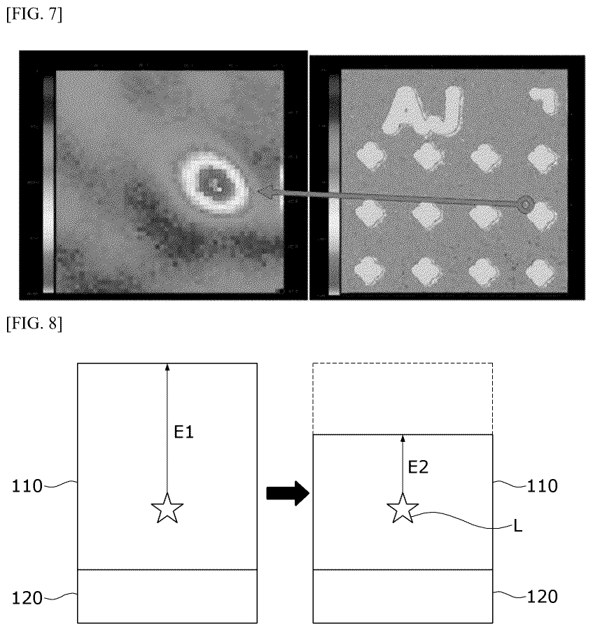

FIG. 7 is an image illustrating the result of mapping a position of a single photon source through the single photon source device according to the embodiment.

Referring to FIG. 7, the single photon source device may reproducibly secure a position of the single photon source by arranging a mapping chart on the wafer. An image of the wafer may be captured through the camera, and the position of the single photon source may be accurately and quickly acquired based on the first sub-chart, the second sub-chart, and the cross patterns of the mapping chart from the captured image.

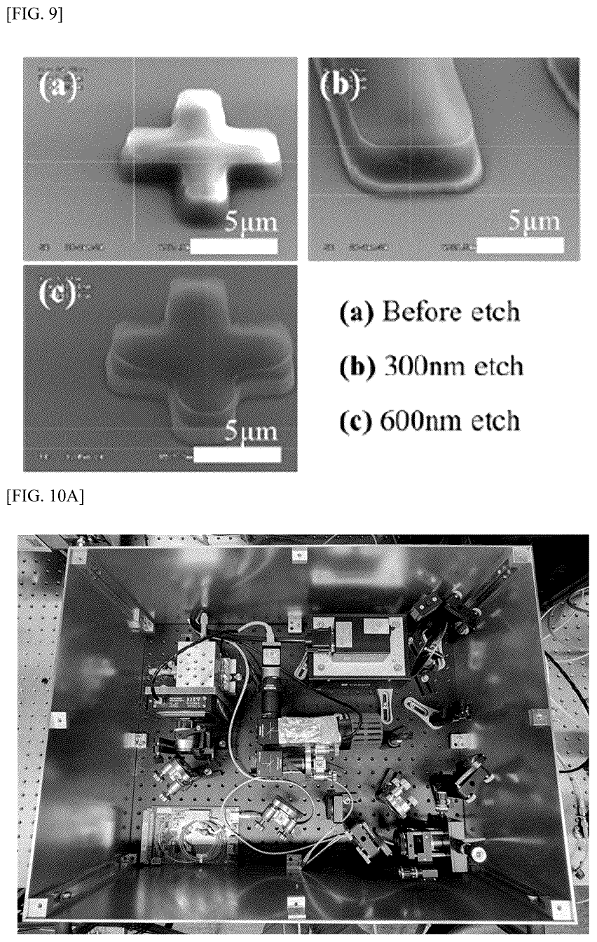

FIG. 8 is a reference diagram illustrating an operation of etching the wafer of the single photon source device according to the embodiment, and FIG. 9 shows images illustrating a state of the etched wafer of the single photon source device according to the embodiment.

Referring to FIGS. 8 and 9, the wafer layer 110 of the wafer 100 of the single photon source device may be etched to have a predetermined height. The wafer layer 110 may be etched to have a predetermined height in the direction in which light is incident, i.e., in a direction perpendicular to the surface of the wafer 100. FIG. 8A shows a state of the wafer layer before etching, and FIG. 8B shows a state of the wafer layer after etching. For example, a distance of 1.3 μm from a surface of the wafer layer 110 to a point L at which a single photon is generated before the etching may be reduced to a distance of 0.7 μm from the surface of the wafer layer 110 to the point L at which the single photon is generated after the etching. For example, an etching height of the wafer layer 110 may range from 0.6 μm to 1.2 μm. The wafer layer 110 is etched so that the surface of the wafer of the single photon source device may be etched, and thus brightness of the single photon source can be increased.

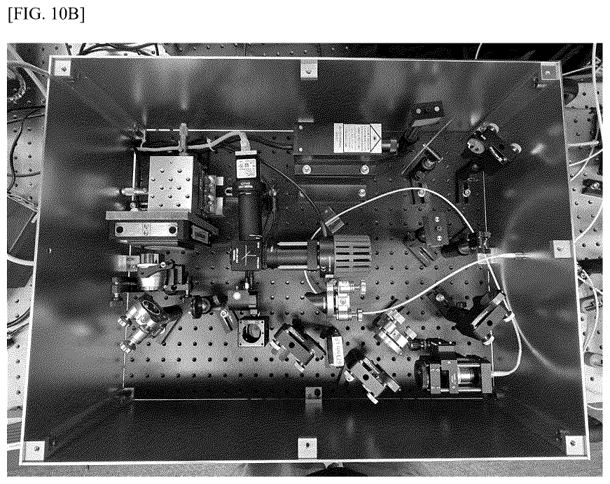

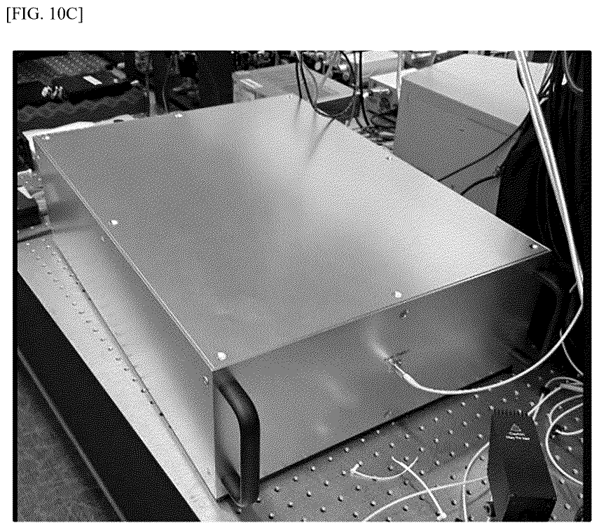

FIGS. 10A to 10C are images of the single photon source device according to the embodiment.

Referring to FIG. 10, the single photon source device may be formed as a single device integrated into a 19-inch standard rack metal case. For example, a bottom size of the single photon source device may be 450 mm*600 mm or small, and a height thereof may be 186 mm (4 U) or small. In addition, a weight of the single photon source device may be 10 kg or less, the single photon source device may be capable of performing an air-cooling room temperature operation and may use a single-phase AC power supply with a voltage of 220 V and a frequency of 60 Hz and have power consumption of 500 W or less. The single photon source device is portable and is installed easily. In addition, the single photon source device may implement a plug-and-play operation method and, thus, require no preparation work or setup before a power switch operation. Accordingly, despite repeated power-off and power-on, performance can be maintained and reproducibility can be improved. In addition, the single photon source device can maintain performance at a temperature ranging from 10° C. to 40° C. and humidity ranging from 30% to 65% R.H. or less, thereby improving environmental stability. In addition, the single photon source device can maintain performance even in daily vehicle driving environments to maintain stability against a vibration and can maintain the performance even after a long-term operation for 100 hours or more, thereby maintaining long-term stability.

In the single photon source device according to the embodiment, a center wavelength may range from 700 nm to 800 nm, and a spectral width (full width half maximum (FWHM)) may be 5 nm or less. A photon flux output through a single-mode optical fiber may be 5*10⁵s⁻¹ (500 kcps) or more. In addition, single photon purity of the single photon source device may be g(2)(0)<0.5, and photon flux output power stability thereof may be 5% or less.

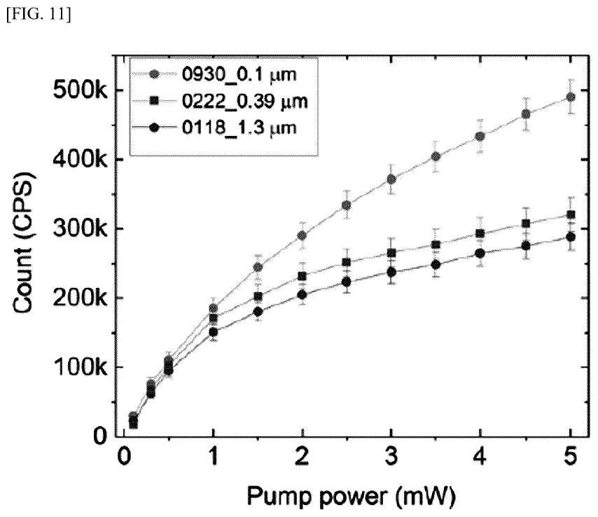

FIGS. 11 to 14 are graphs showing effects of the single photon source device according to the embodiment.

FIG. 11 shows an effect of brightness of the single photon source of the single photon source device when the wafer is etched. This shows a brightness change (CPS) according to pump light (mW) when etch is performed near the surface of the wafer by the single photon source. The graph shows a brightness variation when the etched position are 1.3 μm, 0.3 μm, and 0.1 μm away from a substrate surface. Referring to FIG. 11, it can be confirmed that the brightness of the single photon source increased the most when the etched position was 0.1 μm away from the substrate surface (0930_0.1).

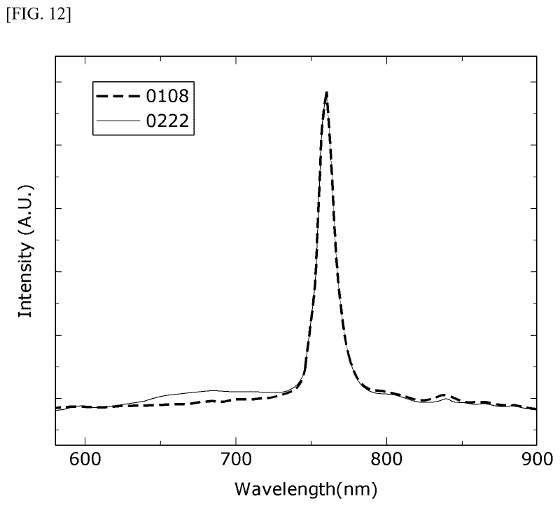

FIG. 12 shows a wavelength distribution of the single photon source of the single photon source device. A center wavelength of the single photon source device according to the embodiments may range from 700 nm to 800 nm.

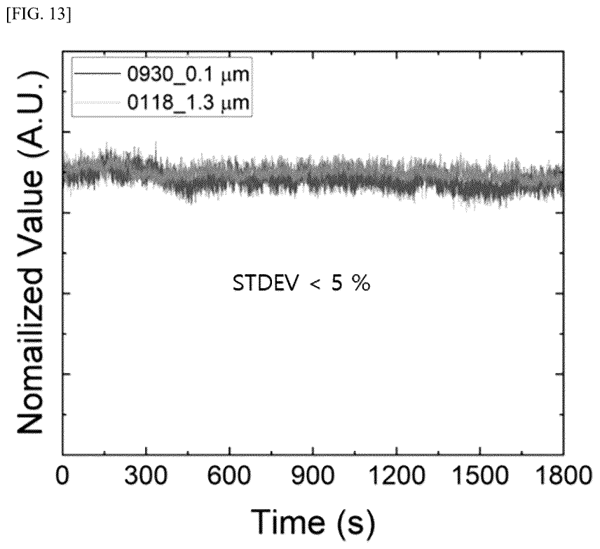

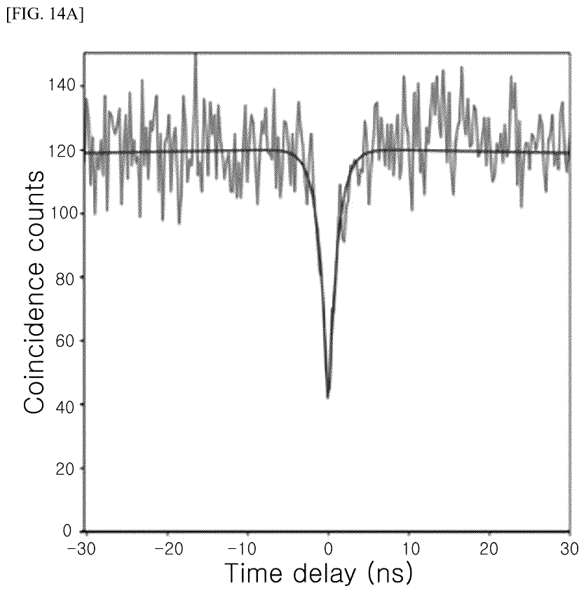

FIG. 13 shows long-term stability of the single photon source device. Photon flux output power stability of the single photon source device may be 5% or less.

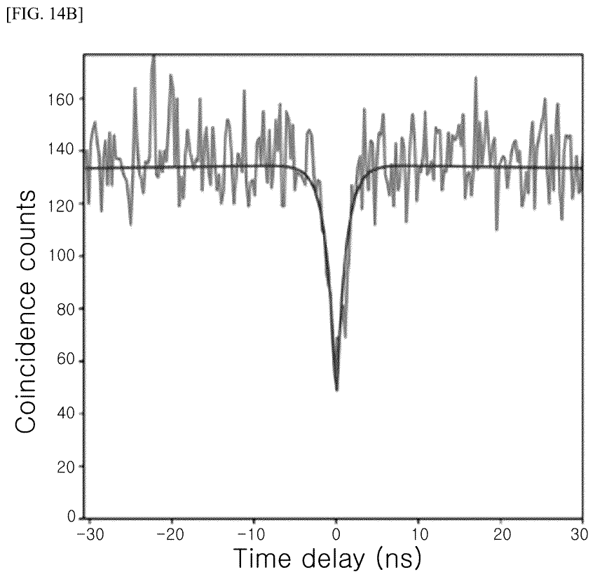

FIGS. 14A and 14B show purity of the single photon source of the single photon source device. Single-photon purity of the single-photon source of the single-photon source device may be g(2)(0)<0.5.

According to embodiments, a single photon source device capable of reproducibly finding a position of a single photon can be provided.

In addition, the single photon source device capable of continuously measuring a light emission intensity can be provided.

In addition, the single photon source device that is operatable at room temperature and is miniaturized can be provided.

The single photon source device with high precision and high stability of photon generation can be provided.

Various beneficial advantages and effects of the present invention are not limited by the detailed description and should be easily understood through a description of a detailed embodiment of the present invention.

While the present invention has been mainly described with reference to exemplary embodiments, it should be understood that the present invention is illustrative and is not limited to the embodiments, and various modifications and applications can be devised by those skilled in the art to which the present invention pertains without departing from the gist of the present invention. For example, each component specifically shown in the exemplary embodiments can be modified and implemented. It should be construed that differences related to these modifications and applications will fall within the scope of the present invention defined by the appended claims.

What is claimed is:

1. A single photon source device comprising:
a microscope part including a stage that is three-dimensionally movable;
a wafer disposed on the stage;
a laser part configured to emit light to the wafer; and
a single-mode fiber (SMF) input/output module configured to emit an optical signal reflected by the wafer to an outside,
wherein the wafer has a surface on which the light is incident and a first mapping chart is disposed, and
the first mapping chart includes a first sub-chart and a second sub-chart, each of which includes a plurality of letters spaced a predetermined distance from each other.

2. The single photon source device of claim 1, wherein the plurality of letters included in the first sub-chart and the plurality of letters included in the second sub-chart are spaced a predetermined distance from each other in a first direction and a second direction perpendicular to the first direction, respectively.

3. The single photon source device of claim 2, wherein the plurality of letters included in the first sub-chart and the plurality of letters included in the second sub-chart are written in directions perpendicular to each other.

4. The single photon source device of claim 3, wherein:
the plurality of letters included in the first sub-chart are written in the first direction; and
the plurality of letters included in the second sub-chart are written in the second direction.

5. The single photon source device of claim 4, wherein:
the plurality of letters included in the first sub-chart are capital letters of English alphabet; and
the plurality of letters included in the second sub-chart are small letters of English alphabet.

6. The single photon source device of claim 5, wherein the plurality of letters included in the first sub-chart include AA to AZ, BA to BZ, and CA to CZ.

7. The single photon source device of claim 5, wherein the plurality of letters included in the second sub-chart include aa to az, ba to bz, and ca to cz.

8. The single photon source device of claim 2, wherein the wafer includes a second mapping chart spaced a predetermined distance from the first mapping chart in the first direction.

9. The single photon source device of claim 8, wherein the distance between the first mapping chart and the second mapping chart ranges from 0.9 cm to 1.1 cm in the first direction.

10. The single photon source device of claim 4, wherein a distance between two adjacent letters among the plurality of letters included in the first sub-chart ranges from 90 μm to 110 μm.

11. The single photon source device of claim 1, wherein the first mapping chart includes a plurality of cross patterns disposed between the plurality of letters included in the first sub-chart and between the plurality of letters included in the second sub-chart.

12. The single photon source device of claim 11, wherein a distance between two adjacent cross patterns among the plurality of cross patterns ranges from 20 μm to 30 μm.

13. The single photon source device of claim 11, wherein the plurality of letters of the first sub-chart and the plurality of letters of the second sub-chart protrude from a surface of the wafer in a direction in which light is incident.

14. The single photon source device of claim 1, further comprising a camera part configured to receive light reflected by the wafer and acquire an image of the wafer.
